(19) United States
(12) Patent Application Publication
(10) Pub. No.: US 2020/0266062 A1
(43) Pub. Date: Aug. 20, 2020

(54) LASER IRRADIATION DEVICE AND LASER IRRADIATION METHOD

(71) Applicant: V Technology Co., Ltd., Yokohama-shi (JP)

(72) Inventor: Michinobu Mizumura, Yokohama-shi (JP)

(21) Appl. No.: 16/869,778

(22) Filed: May 8, 2020

Related U.S. Application Data
(63) Continuation of application No. PCT/JP2018/041566, filed on Nov. 8, 2018.

(30) Foreign Application Priority Data
Jan. 10, 2018 (JP) 2018-0202244

(51) Int. Cl. H01L 21/02; H01L 29/786; H01L 29/66

(52) U.S. Cl. CPC H01L 21/02675; H01L 29/66765; H01L 29/78678

(57) ABSTRACT

A laser irradiation device includes a light source that generates laser light; and a laser head including cylindrical lenses that receive the laser light and generate a thin line laser beam parallel to a moving direction of a substrate, wherein the laser head irradiates a predetermined region of the substrate covered with an amorphous silicon thin film with the thin line laser beam and forms a polysilicon thin film in the predetermined region.

### TECHNICAL FIELD

This disclosure relates to formation of a thin film transistor and, more particularly, a laser irradiation device and a laser irradiation method that radiate laser light onto an amorphous silicon thin film and form a polysilicon thin film.

### BACKGROUND

As a thin film transistor having an inverted staggered structure, there is a thin film transistor in which an amorphous silicon thin film is used for a channel region. However, since the amorphous silicon thin film has low electron mobility, when the amorphous silicon thin film is used for a channel region, there is a problem that the mobility of charges in the thin film transistor is reduced.

Therefore, there is a technique in which a predetermined region of an amorphous silicon thin film is polycrystallized by being instantaneously heated by laser light, a polysilicon thin film having high electron mobility is formed, and the polysilicon thin film is used for a channel region.

For example, Japanese Unexamined Patent Application Publication No. 2016-100537 discloses that an amorphous silicon thin film is formed on a substrate, and then a process in which the amorphous silicon thin film is laser-annealed by being irradiated with laser light such as an excimer laser and the polysilicon thin film is crystallized due to melting and solidifying in a short time is performed. JP '537 discloses that, due to this process being performed, a channel region between a source and a drain of a thin film transistor can be formed as a polysilicon thin film having high electron mobility, and an operational speed of the transistor can be increased.

JP '537 discloses that the entire substrate is irradiated with laser light to perform laser-annealing on a plurality of portions on the substrate. However, a region in which laser-annealing is required on the substrate is a region serving as the channel region between the source and the drain of the thin film transistor and is a partial region of the substrate. Nevertheless, the technique described in JP '537 in which the entire substrate is irradiated with laser light has a problem that extra energy is required for the irradiation of the laser light.

It could therefore be helpful to provide a laser irradiation device and a laser irradiation method in which energy required for radiation of laser light when a predetermined region on a substrate is subjected to laser-annealing is able to be reduced.

### SUMMARY

We thus provide:
A laser irradiation device includes a light source that generates laser light, and a laser head including cylindrical lenses that receive the laser light and generate a thin line laser beam parallel to a moving direction of a substrate, wherein the laser head irradiates a predetermined region of the substrate covered with an amorphous silicon thin film with the thin line laser beam and forms a polysilicon thin film in the predetermined region.
The substrate may include a plurality of predetermined regions in one row parallel to the moving direction, and the laser head may irradiate each of the plurality of predetermined regions included in the one row with the thin line laser beam.
The laser head may include a plurality of cylindrical lenses disposed parallel to the moving direction and may generate a plurality of thin line laser beams with the plurality of the cylindrical lenses.
The substrate may include a plurality of rows each of which includes a plurality of predetermined regions, each of the plurality of rows may be parallel to the moving direction of the substrate, and the laser head may irradiate each of the plurality of rows with each of the plurality of thin line laser beams.
An interval between the plurality of thin line laser beams may be set on the basis of an interval between the plurality of rows on the substrate.
The laser irradiation device may further include a projection mask provided on the laser head and has an opening portion at a position corresponding to the predetermined region of the substrate.
A laser irradiation method includes a first step of generating laser light, a second step of generating a thin linear laser beam parallel to a moving direction of a substrate from the laser light using a cylindrical lens, and a third step of irradiating a predetermined region of the substrate covered with an amorphous silicon thin film with the generated thin line laser beam and forming a polysilicon thin film in the predetermined region.
The substrate may include a plurality of predetermined regions in one row parallel to the moving direction, and in the third step, each of the plurality of predetermined regions included in the one row may be irradiated with the thin line laser beam, and a polysilicon thin film may be formed in the plurality of predetermined regions.

It is possible to provide a laser irradiation device and a laser irradiation method that can reduce the energy required for radiation of laser light when a predetermined region on a substrate is subjected to laser-annealing.

### BRIEF DESCRIPTION OF THE DRAWINGS

FIG. 1A is a schematic top view of a laser irradiation device, and FIG. 1B is a schematic side view of the laser irradiation device.

FIG. 2 is a schematic view showing an example of a thin film transistor in which a predetermined region has been subjected to an annealing treatment.

FIG. 3 is a schematic view showing an example of a substrate.

FIG. 4 is a view for explaining a state in which laser light (a line beam) is radiated on a substrate by a laser irradiation device according to a conventional technique.

FIG. 5 is a schematic diagram explaining a state in which a thin line beam is radiated on a substrate.

FIG. 6 is a schematic diagram explaining a state in which a plurality of cylindrical lenses generate a thin line laser beam.

FIG. 7 is a schematic diagram showing a structural example of a cylindrical lens in a line beam conversion lens member (a laser head).

FIG. 8 is a flowchart showing an operation example of the laser irradiation device.

### EXPLANATION OF REFERENCES

10 Line beam conversion lens member (laser head)
11 Light incident surface
12 Line beam emission surface
15 Base material
20 Thin film transistor
21 Amorphous silicon thin film
22 Polysilicon thin film
23 Source
24 Drain
100 Laser irradiation device
101 Light source
110 Uniform line beam optical system
111 Homogenizer
112 Condenser lens
113 Cylindrical lens
114 Projection mask
115 Mirror
116 Cylindrical lens
117 Semicircular arc
200 Substrate
201, 202, 203 Laser light
204, 205 Line beam
206 Thin line laser beam
300 Stage

### DETAILED DESCRIPTION

Hereinafter, examples of our devices and methods will be specifically described with reference to the accompanying drawings.

### One Example

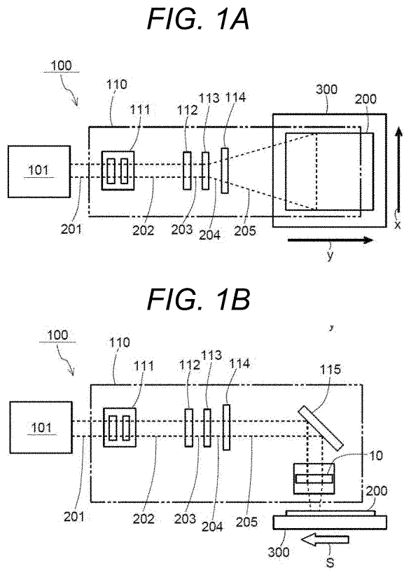

A laser irradiation device according to one example will be described with reference to a schematic side view of FIG. 1B. FIGS. 1A and 1B each are a diagram showing a schematic view of the laser irradiation device. The laser irradiation device 100 is, for example, a device in which laser light is radiated to a region in which a channel region is scheduled to be formed and an annealing treatment is performed to polycrystallize the region in which a channel region is scheduled to be formed in a manufacturing process of a semiconductor device such as a thin film transistor (TFT).

The laser irradiation device 100 is used, for example, when forming a thin film transistor of a pixel such as a peripheral circuit of a liquid crystal display device. When such a thin film transistor is formed, first, a gate electrode made of a metal film made of, for example, Al (aluminum) is patterned on a substrate 200 by sputtering. Then, a gate insulating film made of a SiN (silicon nitride) film is formed on the entire surface of the substrate 200 by a low-temperature plasma chemical vapor deposition (CVD) method.

Then, an amorphous silicon thin film is formed on the gate insulating film by, for example, a plasma CVD method. That is, the amorphous silicon thin film is formed (deposited) on the entire surface of the substrate 200. Finally, a silicon dioxide (SiO₂) film is formed on the amorphous silicon thin film. Additionally, a predetermined region on a gate electrode of the amorphous silicon thin film (a region to be the channel region in the thin film transistor 20) is irradiated with a line beam 205 by a laser irradiation device 100 shown in FIGS. 1A and 1B and is annealed, and thus the predetermined region is polycrystallized into polysilicon. The substrate 200 is, for example, a glass substrate, but the substrate 200 is not necessarily a glass material and may be a substrate of any material such as a resin substrate formed of a material such as a resin.

As shown in FIGS. 1A and 1B, the laser irradiation device 100 includes a light source 101 that generates laser light and also includes a homogenizer 111 that makes an intensity distribution of the laser light emitted from the light source 101 substantially uniform, a condenser lens 112 that condenses the laser light of which the intensity distribution is made uniform by the homogenizer 111, and a cylindrical lens 113 that converts the laser light condensed by the condenser lens 112 into a thin line beam.

Further, a projection mask 114 that reduces interference unevenness that may occur on an irradiation target due to interference of the laser light having passed through the homogenizer 111 is also provided on an optical path between the cylindrical lens 113 and the line beam irradiation target (the substrate 200). In the example shown in the drawing, a mirror 115 and a line beam conversion lens member (a laser head) 10 are provided between the projection mask 114 and the irradiation target (the substrate 200).

The light source 101 is a light source that emits the laser light for laser-annealing. For example, a laser oscillator that oscillates a UV pulse laser, an excimer laser or the like is used. The light source 101 is an excimer laser that emits laser light having a wavelength of 308 nm or 248 nm using a predetermined repeating cycle.

The homogenizer 111 makes the intensity distribution of the laser light 201 oscillated from the light source 101 substantially uniform. The homogenizer 111 includes, for example, two fly-eye lenses that face each other. An aspherical lens, a diffraction optical element or the like is also used for the homogenizer 111.

The condenser lens 112 condenses laser light 202 having passed through the homogenizer 111 and having a substantially uniform intensity distribution.

The cylindrical lens 113 converts laser light 203 condensed by the condenser lens 112 into a line beam. Also, it is also possible to replace the cylindrical lens 113 with the line beam conversion lens member (the laser head) 10.

The projection mask 114 masks a line beam 204 output from the cylindrical lens 113 and then outputs a line beam 205 having a uniform energy distribution. Also, the projection mask 114 may be referred to as a projection mask pattern.

The mirror 115 is a mirror body that reflects the line beam 205 having passed through the projection mask 114 toward the substrate 200 to be irradiated.

The line beam conversion lens member (the laser head) 10 converts the line beam 205 reflected by the mirror 115 into a plurality of thin line beams having a width suitable for irradiating the substrate 200 to be irradiated.

The substrate 200 to be irradiated is a substrate on which a silicon film is formed. The types of substrate are mainly glass types. The substrate 200 is placed on a stage 300.

The stage 300 is a mounting table for mounting the substrate 200 to be laser-annealed. The stage 300 is driven by a driving device (not shown). The substrate 200 moves through the driving of the stage 300, and a surface of the substrate 200 is converted into polysilicon. In the example of FIG. 1B, the stage 300 moves toward the light source 101. The moving direction (S) is also referred to as a scanning direction. Symbols x and y in the drawing are directions in which the stage 300 can move.

The homogenizer 111, the condenser lens 112, the cylindrical lens 113, the projection mask 114, the mirror 115, and the line beam conversion lens member (the laser head) 10 constitute a uniform line beam optical system 110.

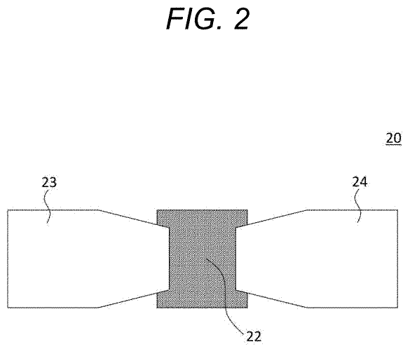

FIG. 2 is a schematic diagram showing an example of the thin film transistor 20 in which a predetermined region has been subjected to an annealing treatment. Also, the thin film transistor 20 is formed by first forming the polysilicon thin film 22 and then forming a source 23 and a drain 24 at both ends of the formed polysilicon thin film 22.

As shown in FIG. 2, in the thin film transistor 20, the polysilicon thin film 22 is formed between the source 23 and the drain 24. The laser irradiation device 100 irradiates a predetermined region of the amorphous silicon thin film with a thin line laser beam. As a result, a predetermined region of the amorphous silicon thin film is instantaneously heated and melted and the polysilicon thin film 22 is formed in a region in which the thin film transistor 20 shown in FIG. 2 is formed.

The polysilicon thin film has higher electron mobility than that of an amorphous silicon thin film and is used in the thin film transistor as a channel region that electrically connects the source to the drain.

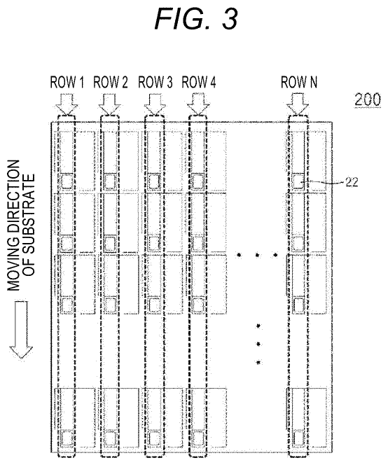

FIG. 3 is a schematic diagram showing an example of the substrate 200 to which a thin line laser beam is radiated by the laser irradiation device 100. As shown in FIG. 3, the substrate 200 includes a plurality of pixels, and each of the pixels includes a thin film transistor. The thin film transistor performs light transmission control in each of the plurality of pixels by being electrically turned on/off.

The laser irradiation device 100 irradiates a predetermined region of the amorphous silicon thin film 21 (a region to be the channel region in the thin film transistor 20) with a thin line laser beam 206. Then, the laser irradiation device 100 irradiates a predetermined region of the amorphous silicon thin film 21 disposed on the substrate 200 with the thin line laser beam 206.

As shown in FIG. 3, a predetermined region to be laser-annealed on the substrate 200, that is, a predetermined region in which the polysilicon thin film 22 is to be formed is disposed in a row parallel to the moving direction of the substrate 200. In the example of FIG. 3, a plurality of predetermined regions are disposed parallel to the moving direction of the substrate 200 in a row 1 that is a row parallel to the moving direction of the substrate 200. Similarly, a plurality of predetermined regions are disposed parallel to the moving direction of the substrate 200 in each of the rows 2 to N that are rows parallel to the moving direction of the substrate 200. As described above, the substrate 200 includes a plurality of rows each of which includes the plurality of predetermined regions and each of the plurality of rows is parallel to the moving direction of the substrate 200. Further, each of the plurality of predetermined regions included in each of the plurality of rows is also disposed parallel to the moving direction of the substrate 200.

As shown in FIG. 3, in the substrate 200, the predetermined region to be laser-annealed, that is, the predetermined region in which the polysilicon thin film 22 is to be formed is disposed in a row parallel to the moving direction of the substrate 200. That is, the region on the substrate that requires laser-annealing is a region that becomes the channel region between the source and the drain of the thin film transistor and is a partial region of the substrate.

In the related art, the entire substrate 200 is irradiated with the laser light (the line beam) using the cylindrical lens provided perpendicular to the moving direction of the substrate 200.

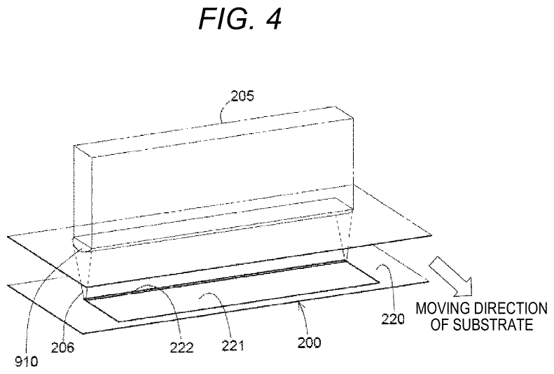

FIG. 4 is a diagram explaining a state in which a laser beam (line beam) is radiated on the substrate 200 by the laser irradiation device 100 in the related art. As shown in FIG. 4, the laser irradiation device 100 in the related art continuously irradiates the substrate 200 with the line beam 206 perpendicular to the moving direction of the substrate 200 by a cylindrical lens 910 provided perpendicular to the moving direction. As a result, the amorphous silicon thin film 220 coated on the substrate 200 is annealed, and thus a polysilicon thin film 221 is formed.

However, as shown in FIG. 3, in the substrate 200, the predetermined region to be annealed is a part on the substrate 200. Nevertheless, as shown in FIG. 4, when the substrate 200 is continuously irradiated with the line beam 206 perpendicular to the moving direction of the substrate 200 by a cylindrical lens 910 provided perpendicular to the moving direction, the line beam 206 is also applied to a portion to which it does not need to be applied, and energy of the laser light is wasted accordingly.

Therefore, our laser irradiation device 100 generates the thin line beam 206 parallel to the moving direction of the substrate 200 by the line beam conversion lens member (the laser head) 10 and irradiates a predetermined region disposed parallel to the moving direction of the substrate 200. That is, the line beam 206 is applied only to a portion of the row 1 to row N in FIG. 3. As a result, in the substrate 200, a portion other than the predetermined region to be annealed (that is, a portion between the rows) is not irradiated with the laser light, and the energy required for irradiation of the laser light can be saved accordingly.

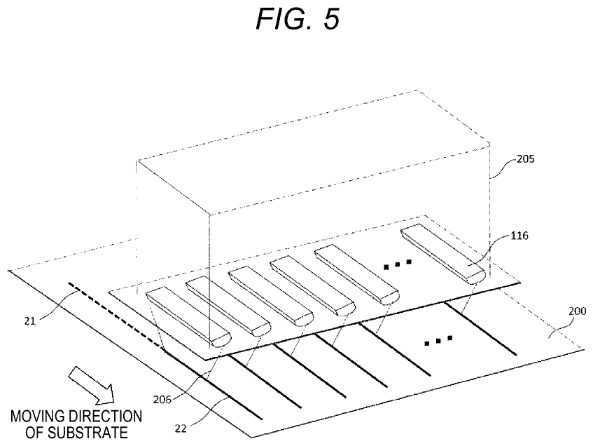

FIG. 5 is a schematic diagram explaining a state in which the thin line beam 206 generated by the line beam conversion lens member (the laser head) 10 is irradiated on the substrate 200. As shown in FIG. 5, the laser light (the line beam 205) passes through the line beam conversion lens member (the laser head) 10 and converts to the thin line laser beam 206 parallel to the moving direction of the substrate 200. The line beam conversion lens member (the laser head) 10 includes a cylindrical lens 116 provided parallel to the moving direction of the substrate 200 and generates the thin line laser beam 206 parallel to the moving direction of the substrate 200 using the cylindrical lens 116.

As shown in FIG. 5, the line beam conversion lens member (the laser head) 10 includes a plurality of cylindrical lenses 116 provided parallel the moving direction of the substrate 200 and can irradiate a plurality of rows (the plurality of rows each of which includes a plurality of predetermined regions) on the substrate 200 with the thin line laser beam 206.

As shown in FIG. 5, the line beam conversion lens member (the laser head) 10 irradiates a predetermined region of the substrate 200, on which the amorphous silicon thin film 21 is coated, with the thin line laser beam 206 and forms the polysilicon thin film 22 in the predetermined region. Further, as shown in FIG. 5, the line beam conversion lens member (the laser head) 10 includes the plurality of cylindrical lenses 116 disposed parallel to the moving direction of the substrate 200 and generates a plurality of thin line laser beams 206 by the plurality of cylindrical lenses 116. The substrate 200 includes a plurality of rows each of which includes a plurality of predetermined regions, and each of the plurality of rows is parallel to the moving direction of the substrate 200. Additionally, the line beam conversion lens member (the laser head) 10 irradiates each of the plurality of rows with each of the plurality of thin line laser beams 206.

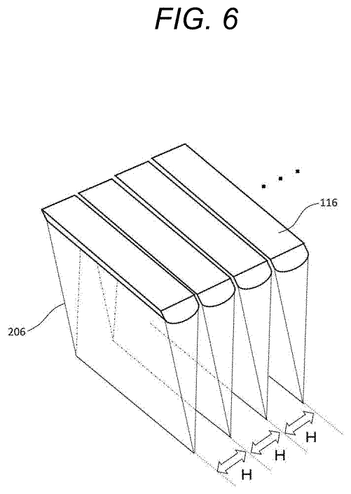

FIG. 6 is a schematic diagram explaining a state in which the plurality of cylindrical lenses 116 generate the thin line laser beam 206.

As shown in FIG. 6, the plurality of cylindrical lenses 116 are disposed in plural, and each of the plurality of cylindrical lenses 116 generates the thin line laser beam 206. An interval H between the thin line laser beams 206 generated by the adjacent cylindrical lenses 116 is set on the basis of an interval between the plurality of rows (the plurality of rows each of which includes a plurality of predetermined regions) on the substrate 200.

As described above, the laser irradiation device 100 applies a plurality of thin line laser beams 206 to a plurality of rows (a plurality of rows each including a plurality of predetermined regions) on the substrate 200. As a result, an irradiation range of the laser light can be limited to a predetermined region of the substrate 200. That is, the laser irradiation device 100 does not radiate the laser beam to a portion between adjacent laser beams 206 on the substrate 200 (a portion of the interval H in FIG. 6). Since a portion between adjacent laser beams 206 (a portion of the interval H in FIG. 6) does not include the predetermined region on the substrate 200 in which the polysilicon thin film 22 is to be formed, this is a region not inherently intended to be irradiated. Therefore, in one example, as compared when the entire substrate 200 is irradiated with the laser light, a range of the irradiation of the laser light can be limited, and the energy required for irradiation of the laser light can be saved.

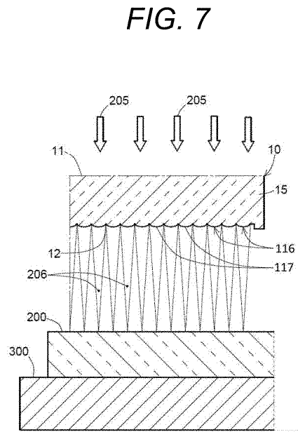

Next, a structural example of the cylindrical lens 116 in the line beam conversion lens member (the laser head) 10 will be described with reference to FIG. 7. Also, in the example of FIG. 7, although a process such as dry etching is performed on a quartz base material 15 to provide the plurality of cylindrical lenses 116, the line beam conversion lens member 10 may be one in which a plurality of independent cylindrical lenses 116 are disposed.

As shown in FIG. 7, the line beam 205 enters the line beam conversion lens member (the laser head) 10 from a light incident surface 11. The line beam conversion lens member (the laser head) 10 includes the plurality of cylindrical lenses 116 and is disposed on the line beam emission surface 12 side of the base material 15 in the line beam conversion lens member (the laser head) 10. Additionally, each of the plurality of cylindrical lenses 116 has a shape of a semicircular arc 117 in a longitudinal cross section of the base material 15 and is convex from the line beam emission surface 12. That is, the plurality of cylindrical lenses 116 are minute convex lenses. The thin line laser beam 206 emitted from the line beam emission surface 12 is radiated to a predetermined region of the substrate 200 mounted on the stage 300.

Regarding the plurality of cylindrical lenses 116 formed on the base material 15, an overall height of the plurality of cylindrical lenses 116 is a distance from the line beam emission surface 12 to a vertex of the semicircular arc 117 (the cylindrical lens 116). The overall height of the cylindrical lens 116 is, for example, 0.1 to 1 mm, but does not necessarily have to be within this range and may be any height. The overall height of the cylindrical lenses 116 is defined by a line width, an energy intensity, a distance between the individual cylindrical lenses 116, and the like. Also, a curvature of the semicircular arc 117 of the cylindrical lens 116 is defined by the overall height, the width of the cylindrical lens 116 itself and the like. The cylindrical lens 116 extends, for example, in a transverse direction of the base material 15, and the cylindrical lens 116 approximates an elongated spindle shape.

A method of forming the cylindrical lens 116 on the line beam conversion lens member (the laser head) 10 is as follows. First, a resist is applied to the quartz base material. The resist is exposed, and a predetermined pattern is formed on a surface thereof. After development, the resist at a portion to be a minute lens portion remains. Then, the surface is heated (reflow). Through the heating, the resist becomes a semicircular arc in longitudinal cross section due to a surface tension. Then, through dry etching, a semicircular convex portion of the minute lens portion is formed on the quartz base material.

According to the method, the cylindrical lenses 116 having a smooth and uniform shape can be formed very simply at one time. Also, since both the base material and the minute lens portion formed thereon are made of quartz and have a common crystal structure, transmittance of the line beam is not reduced.

In addition, the cylindrical lens 116 is long and requires precise curvature adjustment. Due to this fact, there is no manufacturing method therefor other than polishing of the cylindrical lens. Therefore, the cylindrical lens 116 is not easily manufactured because it is easily broken, and time and costs are incurred. However, since a manufacturing method other than the conventional polishing of the cylindrical lens 116 can be applied to formation of the cylindrical lens 116 in the line beam conversion lens member 10, the cylindrical lens 116 having a longer length can be manufactured. Thus, the problem involved with the conventional cylindrical lens 116 can be addressed.

In addition, the cylindrical lens is long and requires precise curvature adjustment. From the fact, there was no manufacturing method other than polishing of the cylindrical lens. Therefore, the cylindrical lens is not easily manufactured because it is easily broken, and it takes time and money. However, since a manufacturing method other than the conventional polishing of the cylindrical lens can be applied to formation of the minute lens portion in the line beam conversion lens member (the laser head) 10, the cylindrical lens having a longer length can be manufactured. Thus, the problem included in the conventional cylindrical lens can be addressed.

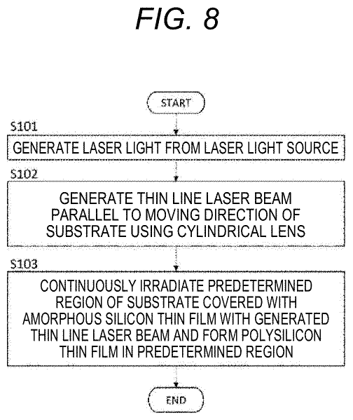

An operation example of the laser irradiation device 100 according to one example will now be described. FIG. 8 is a flowchart illustrating the operation example of the laser irradiation device 100.

As shown in FIG. 8, the light source 101 of the laser irradiation device 100 generates laser light (S101). Next, a thin line laser beam parallel to the moving direction of the substrate is generated from the generated laser light using the line beam conversion lens member (the laser head) 10 including the cylindrical lens (S102). Then, a generated thin line laser beam is continuously radiated to a predetermined region of the substrate on which the amorphous silicon thin film is applied and, thus, a polysilicon thin film is formed in the predetermined region (S103). Then, in another process, the source 23 and the drain 24 shown in FIG. 2 are formed in a thin film transistor in which the polysilicon thin film is formed in the predetermined region.

As described above, the laser irradiation device 100 can limit the irradiation range of the laser light to a predetermined region of the substrate 200, can limit the range to which the laser light is radiated as compared when the entire substrate 200 is irradiated with the laser light and thus can reduce the energy required for irradiation of the laser light.

In the above description, when there is a description such as “vertical,” “parallel,” “plane,” “orthogonal” and the like, these descriptions do not have strict meanings. That is, “vertical,” “parallel,” “plane” and “orthogonal” allow a tolerance or error in design, manufacturing and the like, and mean “substantially vertical,” “substantially parallel,” “substantially plane” and “substantially orthogonal.” A tolerance or error refers to amounts within a range that does not deviate from the configuration, operations and desired effects.

In addition, in the above description, when there is a description such as “same,” “equal,” “different” or the like in appearance dimensions or sizes, the description is not strictly meaning. That is, “same,” “equal” and “different” allow a tolerance or error in design, manufacturing and the like, and mean “substantially the same,” “substantially equal” and “substantially different.” The tolerance or error means a unit within a range that does not deviate from the configuration, operations and desired effects.

Although our devices and methods have been described with reference to the drawings and examples, it should be noted that those skilled in the art can easily make various changes and modifications based on the disclosure. Therefore, such changes and modifications are included in the scope of this disclosure. For example, functions and the like included in each means, each step and the like can be rearranged as long as they are not logically inconsistent, and a plurality of means, steps, and the like can be combined into one or divided. Further, the configurations described in the above examples may be combined as appropriate.

1. A laser irradiation device comprising:
a light source that generates laser light; and
a laser head including cylindrical lenses that receive the laser light and generate a thin line laser beam parallel to a moving direction of a substrate,
wherein the laser head irradiates a predetermined region of the substrate covered with an amorphous silicon thin film with the thin line laser beam and forms a polysilicon thin film in the predetermined region.

2. The laser irradiation device according to claim 1, wherein:
the substrate includes a plurality of predetermined regions in one row parallel to the moving direction, and
the laser head irradiates each of the plurality of predetermined regions included in the one row with the thin line laser beam.

3. The laser irradiation device according to claim 1, wherein the laser head includes a plurality of cylindrical lenses disposed parallel to the moving direction and generates a plurality of thin line laser beams with the plurality of the cylindrical lenses.

4. The laser irradiation device according to claim 3, wherein:
the substrate includes a plurality of rows each of which includes a plurality of predetermined regions,
each of the plurality of rows is parallel to the moving direction of the substrate, and
the laser head irradiates each of the plurality of rows with each of the plurality of thin line laser beams.

5. The laser irradiation device according to claim 4, wherein an interval between the plurality of thin line laser beams is set on the basis of an interval between the plurality of rows on the substrate.

6. The laser irradiation device according to claim 1, further comprising a projection mask provided on the laser head and has an opening portion at a position corresponding to the predetermined region of the substrate.

7. A laser irradiation method comprising:
generating laser light;
generating a thin linear laser beam parallel to a moving direction of a substrate from the laser light using a cylindrical lens; and
irradiating a predetermined region of the substrate covered with an amorphous silicon thin film with the generated thin line laser beam and forming a polysilicon thin film in the predetermined region.

8. The laser irradiation method according to claim 7, wherein:
the substrate includes a plurality of predetermined regions in one row parallel to the moving direction, and
in the irradiation step, each of the plurality of predetermined regions included in the one row is irradiated with the thin line laser beam, and a polysilicon thin film is formed in the plurality of predetermined regions.
